(19) United States
(12) Patent Application Publication
(10) Pub. No.: US 2010/0259278 A1
(43) Pub. Date: Oct. 14, 2010

(54) TESTING CIRCUIT BOARD

(76) Inventors: Wei-Fen CHIANG, Taipei City (TW); Yung-Wang Chia, Taipei City (TW)

Correspondence Address: Muncy, Geissler, Olds & Lowe, PLLC, 4000 Legato Road, Suite 310, FAIRFAX, VA, 22033, US

(21) Appl. No.: 12/756,671

(22) Filed: Apr. 8, 2010

(30) Foreign Application Priority Data
Apr. 10, 2009 (TW) 098205849

(51) Int. Cl. G01R 31/02

(52) U.S. Cl. 324/537

(57) ABSTRACT

A testing circuit board mounted on a testing machine is provided and utilized for testing at least one device under test (DUT). The testing circuit board includes at least one first testing circuit and a plurality of signal communication terminals. The first testing circuit directly formed by circuit printing means includes at least one test slot for holding the DUT to be tested. The signal communication terminals are utilized for receiving a plurality of testing signals from the testing machine, testing the DUT by transmitting the plurality of testing signals to the at least one test slot through the at least one first testing circuit, and transmitting a plurality of output signals from the o DUT to the testing machine.

### CROSS REFERENCE TO RELATED APPLICATIONS

This Application claims priority of Taiwan Patent Application No. 098205849, filed on Apr. 10, 2009, the entirety of which is incorporated by reference herein.

### BACKGROUND OF THE INVENTION

1. Field of the Invention

The present invention relates to a testing circuit board, and in particular relates to a testing circuit board for testing a device under test.

2. Description of the Related Art

To ensure the quality of integrated circuits when shipment, each of the produced integrated circuits (ICs) must be tested and qualified according to established testing results, thereby determining whether these ICs can be supplied to the downstream factories or not.

FIG. 1 is a schematic view of a testing configuration utilized to test a conventional integrated circuit mass production. In the testing configuration, a tester 10 is utilized to test a device under test (DUT) 22 such as an integrated circuit under test. To facilitate the process of testing, the DUT 22 is generally mounted on a device under test board (DUT board) 20.

Referring also to FIG. 2, FIG. 2 is a schematic view of a conventional testing circuit board. As shown in FIGS. 1 and 2, in the testing process, the tester 10 is generally incorporated with a dedicated DUT board 20, and different DUTs 22 are individually provided to a corresponding circuit of the DUT board 20. In the dedicated DUT board 20, a connection terminal 24 (e.g., distributed power supply (DPS), relay control, channel, CBIT terminal, universal ports, etc.) is generally provided for performing basic tests on the DUT 22.

In addition, a method is provided to solve problems caused by manual lead connection. The method provides a testing circuit formed on a printed circuit board and a plurality of cable slots respectively mounted on the printed circuit board and the DUT board, thereby transmitting the testing signal to the printed circuit board for testing the DUT.

### BRIEF SUMMARY OF THE INVENTION

When testing ICs, the DUT boards are conventionally manufactured by manual lead connections, and thus the debug process for wrong connections caused by the manual lead connections is time-consuming. Although the problems caused by the manual lead connections can be prevented by a connected printed circuit, as if the DUT is required to perform in the environment over a high voltage and at least 20 MHZ frequency while being tested, the interference caused by a cable under signal transmission causes testing errors. To overcome the aforementioned problems, a testing circuit board is provided. The testing circuit board of the invention is mounted on a testing machine for testing at least one device under test. The testing circuit board includes at least one first testing circuit and a plurality of signal communication terminals. The first testing circuit directly formed by circuit printing means includes at least one test slot for holding the DUT to be tested. The signal communication terminals are utilized for receiving a plurality of testing signals from the testing machine, testing the device under test by transmitting the plurality of testing signals to the test slot through the first testing circuit, and transmitting a plurality of output signals from the device under test to the testing machine.

With the testing circuit board of the embodiment, production efficiency can be increased and the problems caused by manual lead connections can be prevented. Because the testing can be completed by a single testing circuit board, the interference caused by a cable under signal transmission can be eliminated. Thus, the testing process can be simplified, the efficiency can be increased, and the resultant data of the testing can be relatively accurate.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a schematic view of a testing configuration utilized to test a conventional integrated circuit mass production;

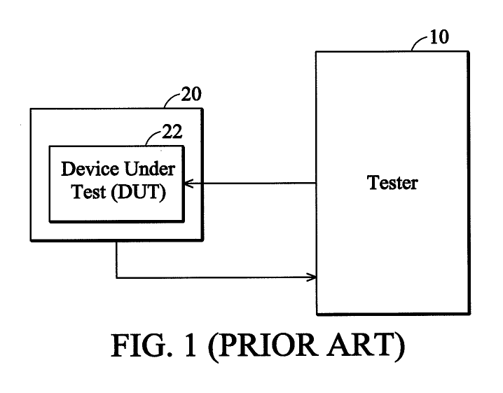

FIG. 2 is a schematic view of a conventional testing circuit board;

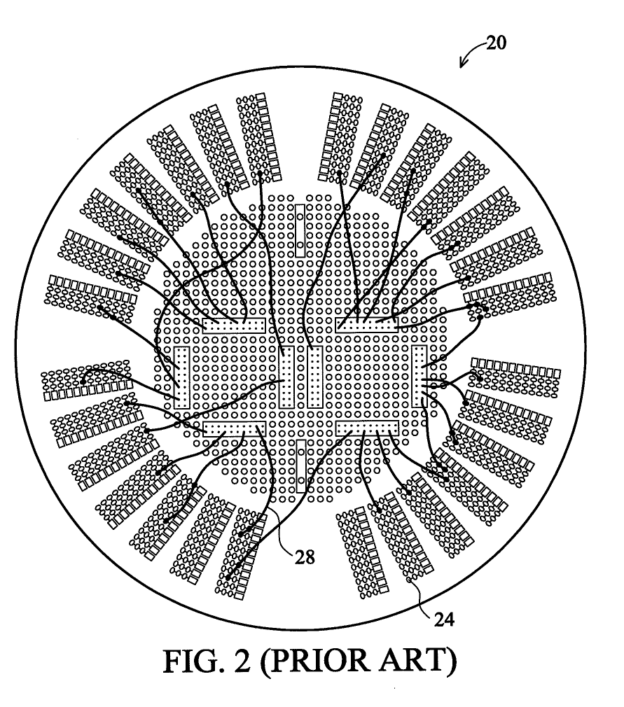

FIG. 3 is a schematic view (front view) of a testing circuit board of the present invention;

FIG. 4 is a schematic view (rear view) of a testing circuit board of the present invention;

FIG. 5 is a schematic view of a testing machine;

FIG. 6 is a schematic view of a locking/fastening disk of a testing machine; and

FIG. 7 is a schematic view showing a testing circuit board mounted on a testing machine.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

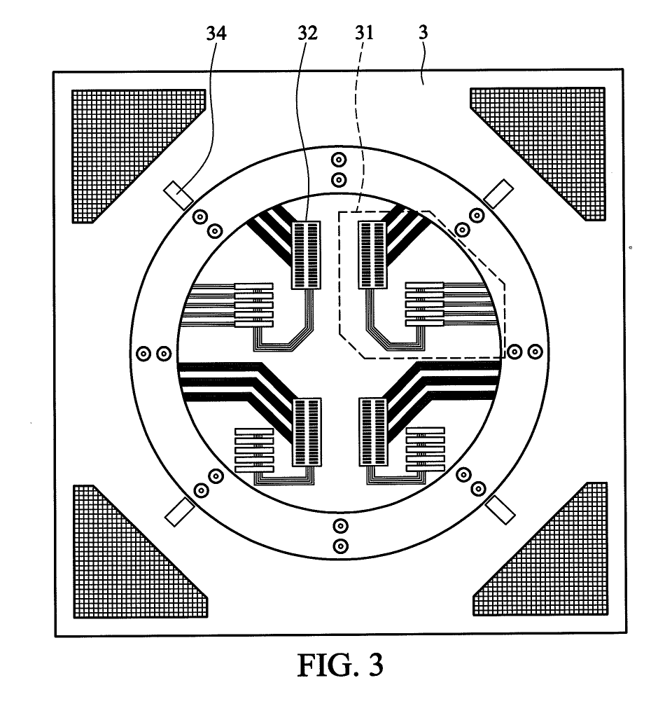

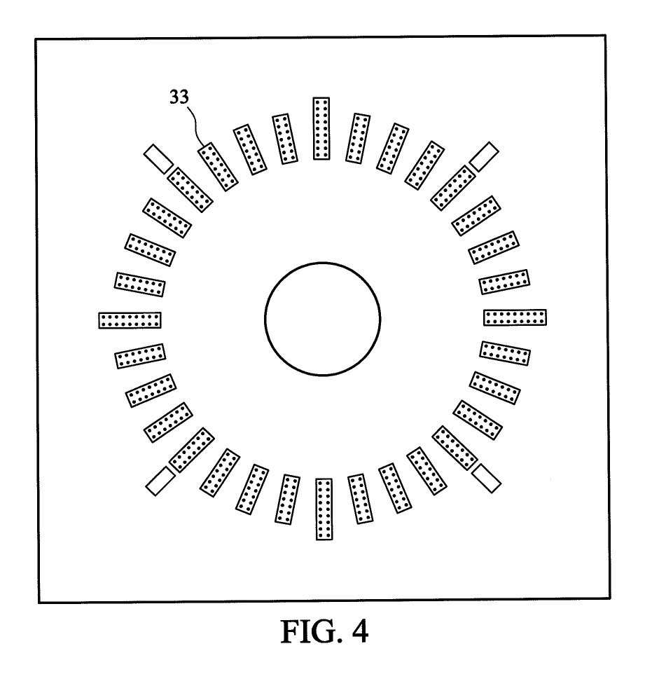

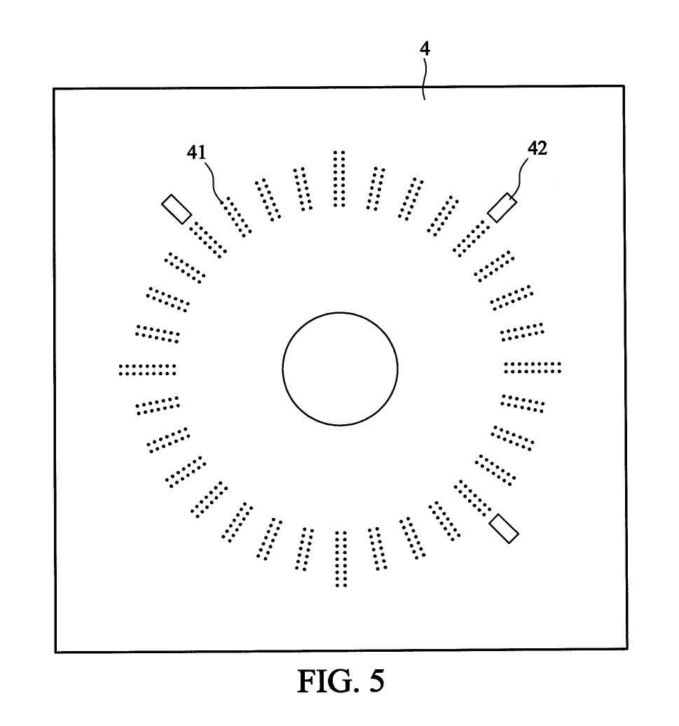

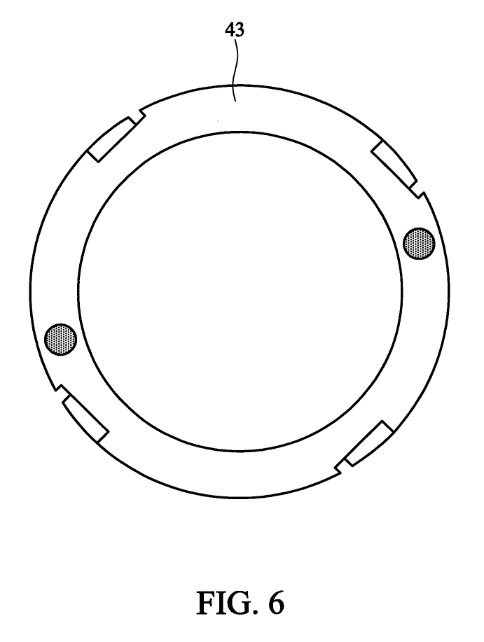

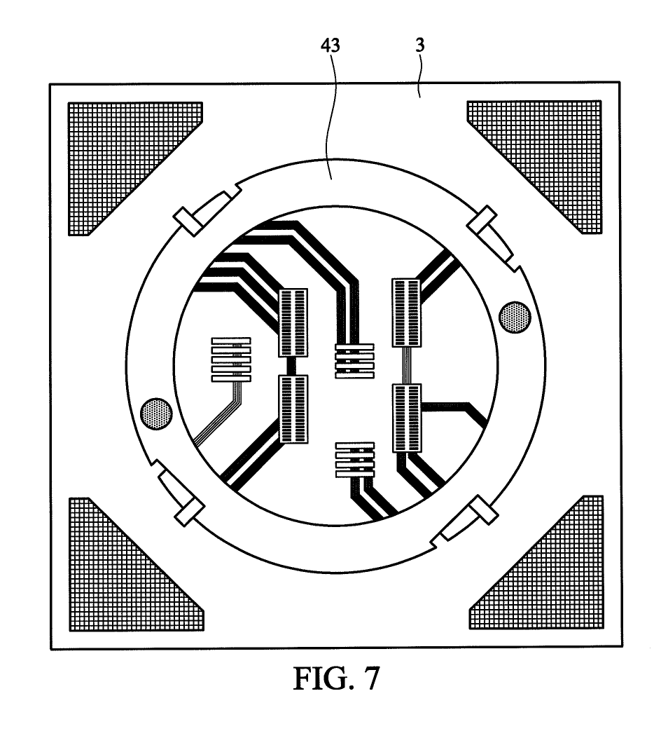

In FIGS. 3 to 7, a testing circuit board 3 mounted on a testing machine 4 for testing four devices under test (DUT) includes at least one first testing circuit directly formed by circuit printing means, a plurality of signal communication terminals 33, and a plurality of latching holes 34. In this embodiment, the testing machine 4 is a VTT V8000 testing machine produced from VLSI TEST TECHNOLOGY Inc.

The first testing circuit includes four sets of second testing circuits 31. Each second testing circuit 31 includes a test slot 32 for holding the device under test to be tested.

The signal communication terminals 33 are utilized to receive a plurality of testing signals transmitted from a pin header 41 of the testing machine 4. The testing signals are transmitted to the test slots 32 via the second testing circuit 31 for testing the four devices under test and a plurality of output signals correspondingly generated by the DUT according to the testing signals are transmitted to the testing machine 4.

The latching holes 34 are correspondingly connected to the latching posts 42 located on the testing machine 4, and the testing circuit board 3 can be stably mounted on the testing machine 4 via a locking/fastening disk 43 located on the testing machine 4. In this embodiment, the latching holes can be latching posts dependent upon the testing method of the testing machine utilized.

In the testing circuit board 3, the DUT includes an integrated circuit or a wafer. Furthermore, the DUT includes a first device capable of performing in the environment over a high voltage and at least 20 MHZ frequency while being tested, thereby obtaining excellent effects compared to other methods or other testing circuit boards.

With the testing circuit board of the embodiment, production efficiency can be increased and the problems caused by manual lead connections can be prevented. Because the testing can be completed by a single testing circuit board, the interference caused by a cable under signal transmission can be eliminated. Thus, the testing process can be simplified, the efficiency can be increase and the resultant data of the testing is relatively accurate.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A testing circuit board mounted on a testing machine for testing at least one device under test, comprising:
at least one first testing circuit formed by circuit printing means, wherein the at least one first test circuit includes at least one test slot for holding the at least one device under test to be tested; and
a plurality of signal communication terminals for receiving a plurality of testing signals from the testing machine, testing the at least one device under test by transmitting the plurality of testing signals to the at least one test slot through the at least one first testing circuit, and transmitting a plurality of output signals from the at least one device under test to the testing machine.

2. The testing circuit board as claimed in claim 1, wherein the at least one first testing circuit includes four sets of second testing circuits for testing four devices under test simultaneously.

3. The testing circuit board as claimed in claim 1 further comprising a plurality of latching posts or latching holes for mounting the testing circuit board on the testing machine.

4. The testing circuit board as claimed in claim 1, wherein the testing machine includes a VTT V8000 testing machine.

5. The testing circuit board as claimed in claim 1, wherein the at least one device under test includes an integrated circuit or a wafer.

6. The testing circuit board as claimed in claim 1, wherein the at least one device under test includes a first device capable of performing in the environment over a high voltage and at least 20 MHZ frequency.
